(19) United States
(12) Patent Application Publication
(10) Pub. No.: US 2005/0110142 A1
(43) Pub. Date: May 26, 2005

(54) Diffusion barriers formed by low temperature deposition

(76) Inventors: Michael Wayne Lane, Cortlandt Manor, NY (US); Christian C. Lavoie, Ossining, NY (US); Sandra G. Malhotra, Beacon, NY (US); Fenton R. McFeely, Ossining, NY (US); John Jacob Yurkas, Stamford, CT (US)

Correspondence Address: KEUSEY, TUTUNJIAN & BITETTO, P.C., 14 VANDERVENTER AVENUE, SUITE 128, PORT WASHINGTON, NY, 11050, US

(21) Appl. No.: 10/722,934

(22) Filed: Nov. 26, 2003

(51) Int. Cl. H01L 23/48; H01L 21/4763; H01L 29/40

(52) U.S. Cl. 257/751; 438/627; 438/643; 257/774; 438/629

(57) ABSTRACT

A solid state device includes a first material and a second material. A barrier layer is formed between the first material and the second material to prevent diffusion between the first material and the second material. The barrier layer includes a metal form of at least one of Ru and Re. The barrier layer is preferably formed using a low temperature deposition process, where the substrate is less than 400 degrees C.

### BACKGROUND OF THE INVENTION

1. Field of the Invention

This invention relates to forming diffusion barriers, and more particular to devices and methods for forming diffusion barriers for wiring structures in semiconductor devices by depositing thin metallic films using chemical vapor deposition (CVD).

2. Description of the Related Art

Diffusion barriers are employed in semiconductor fabrication processes to reduce diffusion or the exchange of atoms between two regions. For example, copper wiring for integrated microelectronic circuit technology may use a diffusion barrier material to prevent the diffusion of the copper, which forms wires, into a matrix of dielectric where the wires are embedded.

To produce metal films of usable quality for diffusion barriers, a substrate must be subjected to elevated temperatures during deposition. If the temperature required to deposit a film with useful barrier properties is greater than about 400 degrees C., the process may not be compatible with a variety of otherwise useful dielectric materials, as these materials may not be chemically stable at these elevated temperatures. Even if the dielectric is chemically stable, the high temperature excursion has the potential of damaging the dielectric wiring structure at least through thermal expansion coefficient mismatches between the metal wiring structures and the dielectric matrix in which they are embedded.

An example of the difficulties that can arise from temperature restrictions to less than 400 degrees C. is exemplified by the production of tungsten barrier films using chemical vapor deposition (CVD) from W(CO)₆. At temperatures around 400 degrees C., the barrier properties of the films deposited by this method are excellent, and the W produced has excellent resistivity, e.g., as low as about 25 microohm-cm, depending upon the film thickness and the deposition conditions. As the deposition temperature is lowered, two properties change. First, the resistivity of the films increases. This is in principle undesirable, because the barrier film is part of the current carrying structure. Second, as the deposition temperature falls, a different, metastable phase of W, beta W, is formed, and films including beta W are no longer useful diffusion barriers. For practical, as opposed to laboratory, deposition conditions, it is therefore difficult to extend this process below about 400 degrees C.

Accordingly, CVD processes which can deposit useful barrier films at temperatures substantially less than 400 C. would be highly desirable. A further need exists for a barrier film, which can be deposited at a temperature of 350 degrees C. or less, which still has reasonably good resistivity, and barrier properties.

### SUMMARY OF THE INVENTION

A solid state device includes a first material and a second material. A barrier layer is formed between the first material and the second material to prevent diffusion between the first material and the second material. The barrier layer includes a metal form of at least one of Ru and Re. The barrier layer is preferably formed using a low temperature deposition process, where the substrate is less than 400 degrees C., and more preferably below a temperature of 350 degrees C.

These and other objects, features and advantages of the present invention will become apparent from the following detailed description of illustrative embodiments thereof, which is to be read in connection with the accompanying drawings.

### BRIEF DESCRIPTION OF DRAWINGS

The invention will be described in detail in the following description of preferred embodiments with reference to the following figures wherein:

FIG. 1 is a cross-sectional view of a solid state device or semiconductor device showing trenches formed in a first material;

FIG. 2 is a cross-sectional view of the device of FIG. 1 after depositing and processing a barrier layer in accordance with the present invention;

FIG. 3 is a cross-sectional view of the device of FIG. 2 after depositing and processing a conductor material over the barrier layer in accordance with the present invention;

FIG. 4 is a plot of film resistivity versus deposition temperature for a Ru deposition process in accordance with the present invention; and

FIG. 5 is a plot of film resistivity versus film thickness for a Ru deposition process in accordance with the present invention.

### DETAILED DESCRIPTION OF PREFERRED EMBODIMENTS

The present invention provides a diffusion barrier, which is formable at low temperatures, e.g., below 400 degrees C., and preferably below 350 degrees C. For feature sizes below about 0.1 microns, chemical vapor deposition (CVD) may be employed for the fabrication barrier layers since CVD provides high inherent conformality. In one embodiment, a copper conductor may be employed with a barrier film interface. The barrier is formed from Ru or Re compounds and can be at least at least as low in resistance than barrier films made from Tungsten (W) while being deposited at a substantially lower temperature. In addition, barrier layers made from Ru or Re have a much higher tolerance to processing effects for example, adhesion to the dielectric is maintained after additional process steps are performed than W films deposited at the corresponding low temperature.

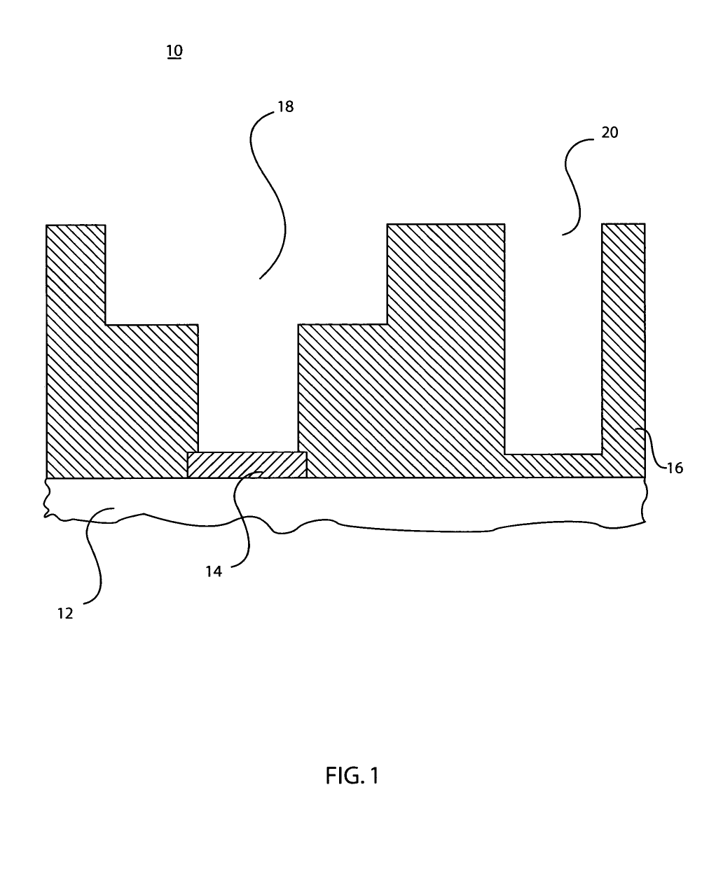

It should be understood that FIGS. 1-3 show an illustrative semiconductor or solid state device structure to demonstrate particularly useful embodiments of the present invention. However, many other structures and applications are contemplated and may benefit from the use of the barrier layers and the formation processes as outlined herein.

Referring now in detail to the figures in which like numerals represent the same or similar elements and initially to FIG. 1, an illustrative structure 10, which employs barrier layers, is shown in accordance with an exemplary embodiment of the present invention. Structure 10 may be referred to herein as a substrate. An underlying layer 12 or structure may be provided depending on the type of semiconductor device or apparatus in which the barrier layer is needed. Layer 12 may include a semiconductor substrate, dielectric material, conductive material or any combination thereof. In one example, layer 12 includes a semiconductor substrate, e.g., Si crystal or silicon on insulator, GaAs, or any other substrate material. In other examples, underlying layer includes a combination of conductors embedded in a dielectric material.

A conductor 14 is shown which may have been formed in previous processing steps. A layer 16 is formed and opened up to form trenches 18 and 20. It should be noted that trenches 18 and 20 may be formed in some embodiments directly into a semiconductor substrate. However, for the embodiment described layer 16 is a dielectric layer. Material for dielectric layer 16 may be any suitable dielectric material, including organic or inorganic dielectrics.

Trench 18 may be formed in a dual damascene process while trench 20 may be formed by any trench forming process. Such processes may include lithographic processing which may include forming masks, patterning the mask and performing an etch process, such as an anisotropic etching process. As illustratively shown, trench 18 exposes conductor 14 to ensure a conductive path to features or structures in underlying layer 12.

Surfaces of trenches 18 and 20 may now be prepared for the formation of diffusion barrier films in accordance with the present invention. Diffusion barrier films are preferably uniform and thin in thickness (e.g., less than about 7000 Angstroms), and consistent, that is, little or no holes or inconsistencies in the structure.

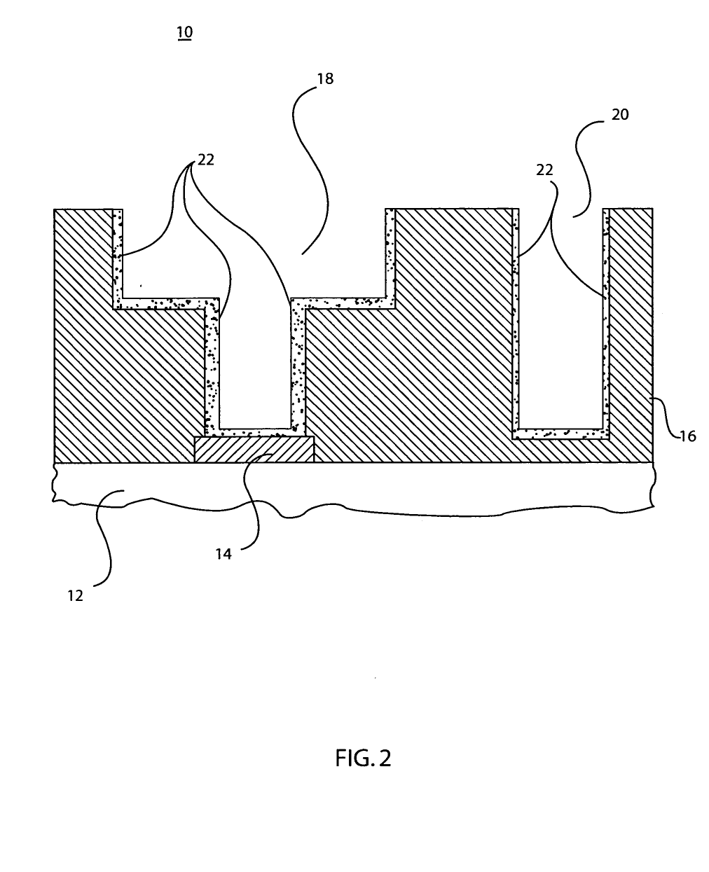

Referring to FIG. 2, to deposit the barrier films of the present invention, it is preferable to employ a chemical vapor deposition (CVD) process since the resulting film is uniform and consistent. However, other processes may be employed as well, for example, sputtering.

In accordance with the present invention, ruthenium, rhenium and alloys thereof are employed to form barrier layer 22. Metal carbonyls of these metals are preferably employed as a precursor in the deposition processes. In one embodiment, ruthenium deposition employs Ru₃(CO)₁₂ as the ruthenium precursor. The CVD process may be carried out, by employing, e.g., a cold wall stainless steel Metal Organic Chemical Vapor Deposition (MOCVD) reactor by means of a load lock and a vacuum transfer apparatus. The reactor may be pumped by a turbomolecular pump with a base pressure of, for example, less than 1×10⁻⁷ ton.

The structure may be heated to deposition temperature by, for example, a boron nitride enclosed resistive heating element. Other heating elements or methods may also be employed.

A low temperature CVD process preferably includes substrate temperatures of between 300 and 400 degrees C. Lower temperatures may also be employed for example, as low as 250 degrees C. to form barrier layer 22. The Ru precursor may be entrained in hydrogen, argon or other inert gas and dispensed onto the substrate by via, e.g., a thermostatted showerhead applicator.

To provide adequate vapor pressure, the precursor, the showerhead and the associated delivery lines may be held at between about 45 and about 60 degrees C. This may be adjusted depending on the process needs. In the illustrative embodiment, the chamber pressure was maintained between about 10 and about 100 mtorr during the deposition processes. Under these conditions, growth rates of between about 1 and about 10 nm/min can be achieved.

In another embodiment under similar conditions, rhenium deposition employed Re₂(CO)₁₀ as the rhenium precursor.

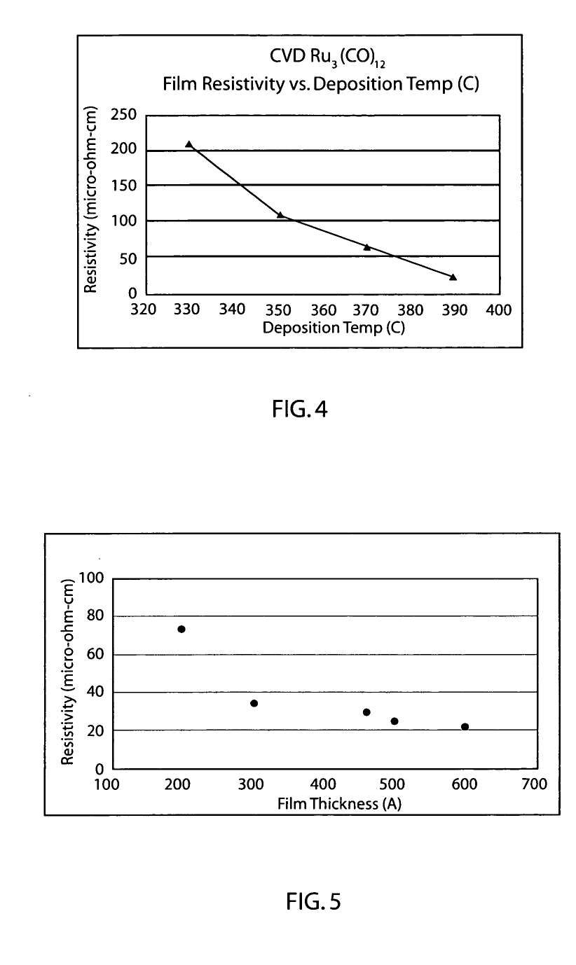

The illustrative process was employed to deposit ruthenium and rhenium films onto silicon and silicon dioxide substrates to test the films. FIG. 4 is a plot of the resistivity of Ru films deposited in this manner as a function of substrate temperature. The resistivity is seen to gradually increase as the substrate temperature is decreased. It should be noted that the absolute value of the resistivity depends upon more parameters than the substrate temperature, and it would be possible to minimize the resistivity increase with decreasing temperature by optimizing the deposition parameters at each temperature separately. This data set was not optimized in this way. Instead, the data set is provided to show a general trend in resistivity versus temperature for the barrier films deposited by a low temperature process. One aspect of this data is that the resistivity increase is a gradual, continuous process, and does not exhibit discontinuous or abrupt changes which may signal the onset of the deposition of other crystalline phases which could compromise the diffusion barrier properties in a manner analogous to the situation in W films as mentioned above.

The results of the plot in FIG. 4 were further verified by x-ray diffraction measurements, which showed surprisingly that the Ru films retained the thermodynamically stable hexagonal close packed (hcp) phase throughout the temperature range studied.

Films of Re were deposited in the same reactor and in the same manner employed for Ru. The resistivity showed qualitatively the same behavior exhibited by the Re films, and x-ray diffraction showed similar constancy of the thermodynamically stable hcp phase throughout the 300-400 degrees C. range.

Referring again to FIG. 2, after deposition of barrier layer 22, other processing steps may include planarization by chemical and/or mechanical polishing steps to remove, barrier layer 22 from surfaces, for example, the top surface of the workpiece or substrate.

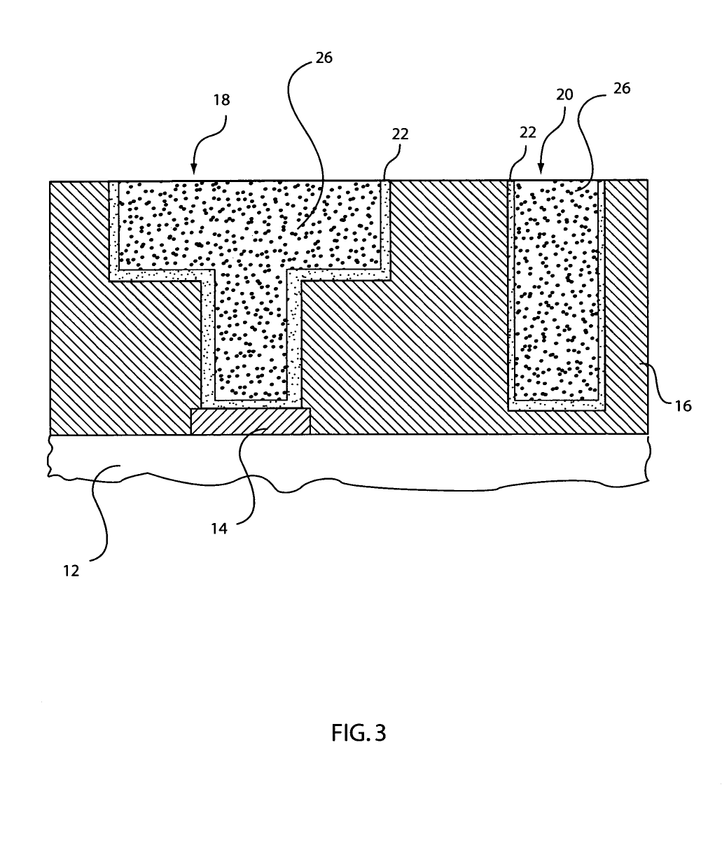

Referring to FIG. 3, conductive material 26 is deposited in trenches 18 and 20 over diffusion barrier 22. In one embodiment, the conductive material 26 may include copper and/or its alloys. In other embodiments, gold, silver, aluminum, titanium, or other metals and their alloys may be employed. In still other embodiments, conductive material 26 may include doped polycrystalline materials, such as polysilicon. After deposition of conductive material 26, planarization steps may be performed. This may be followed by continued processing, which may include additional layers of dielectric material with embedded wiring including barrier layers in accordance with the present invention. By providing low temperature deposition, thermal budget for future semiconductor processing is advantageously conserved.

Referring to FIG. 5, a determination of diffusion barrier properties in accordance with the present invention was performed. The test structures for diffusion barrier efficacy were fabricated by depositing a set of Ru and Re films of thicknesses ranging from 5.0 to 12.0 nm at substrate temperatures of 330-370 degrees C. onto bare Si substrates. Approximately 50 nm of Cu was then sputter deposited onto the Ru and Re films to provide the Cu source for barrier testing. The barrier testing was carried out by temperature ramp x-ray diffraction, using a synchrotron x-ray source.

In this method, the x-ray diffraction spectrum was continuously measured over a range of 20 deg. in 2 theta, (2 theta is determined from a surface normal to the material and theta is the angle of incidence of the x-rays) as the substrate temperature was ramped at approximately 3 degrees C./sec from room temperature up to 1000 degrees C. If the barrier material becomes permeable to Cu at any point, the Cu will diffuse into and react with the substrate Si. The resulting copper silicide then gives rise to new diffraction features at characteristic 2 theta values. The results of this analysis remarkably indicate that even the thinnest Re films remained robust diffusion barriers up to at least 900 C. The Ru films remained robust at least up to 550 C., because at this point the Ru reacted with the Si substrate. However, up to that temperature there was no indication of the failure of the barrier. Thus, 550 C. can be regarded as a lower bound for the failure temperature of Ru barriers. As this temperature is already more than 100 degrees C. larger than any temperature the wiring structures are likely to experience during processing, this is already regarded as sufficient for practical applications.

Having described preferred embodiments for diffusion barriers formed by low temperature deposition (which are intended to be illustrative and not limiting), it is noted that modifications and variations can be made by persons skilled in the art in light of the above teachings. It is therefore to be understood that changes may be made in the particular embodiments of the invention disclosed which are within the scope and spirit of the invention as outlined by the appended claims. Having thus described the invention with the details and particularity required by the patent laws, what is claimed and desired protected by Letters Patent is set forth in the appended claims.

1. A solid state device comprising:
a first material;
a second material;
a barrier layer formed between the first material and the second material to prevent diffusion between the first material and the second material, the barrier layer includes a metal form of at least one of Ru and Re.

2. The device as recited in claim 1, wherein the metal form includes a hexagonal close packed structure.

3. The device as recited in claim 1, wherein the first material is a dielectric and the second material is a metal.

4. The device as recited in claim 1, wherein the first material is a conductor and the second material is a metal.

5. The device as recited in claim 1, wherein the first material includes copper.

6. The device as recited in claim 1, wherein the metal form includes a single metallic phase in a temperature range of between about 300 degrees C. and about 550 degrees C.

7. The device as recited in claim 1, wherein the metal form includes a single metallic phase in a temperature range of between about 300 degrees C. and about 900 degrees C.

8. The device as recited in claim 1, wherein device is a semiconductor device and the first material includes a semiconductor material.

9. The device as recited in claim 1, wherein the barrier layer includes a thickness of 700 Angstroms or less.

10-20. (canceled)

21. A solid state device comprising:
a first material;
a second material;
a barrier layer formed between the first material and the second material to prevent diffusion between the first material and the second material, the barrier layer includes a metal form of Ru.

22. A solid state device comprising:
a first material;
a second material;
a barrier layer formed between the first material and the second material to prevent diffusion between the first material and the second material, the barrier layer includes a metal form of Re.
